(19) United States
(12) Patent Application Publication
(10) Pub. No.: US 2002/0054520 A1
(43) Pub. Date: May 9, 2002

(54) Method for generating a second address

(76) Inventors: Frank Bahren, Karlsruhe (DE); Joachim Wietzke, Karlsruhe (DE); Harald Schopp, Ettlingen (DE); Joachim Bischoff, Keltern (DE); Dirk Lappe, Karlsruhe (DE); Stefan Wolf, Muehltal (DE)

Correspondence Address: Samuels, Gauthier & Stevens LLP, Suite 3300, 225 Franklin Street, Boston, MA, 02110, US

(21) Appl. No.: 09/892,783

(22) Filed: Jun. 27, 2001

(30) Foreign Application Priority Data
Jun. 28, 2000 (DE) 100 30 522.9

(51) Int. Cl. G11C 29/00

(52) U.S. Cl. 365/200

(57) ABSTRACT

To avoid misconnections and to increase data protection during communication between devices (1 to 9), which are linked with one another in a first network (M) and devices linked with one another in a second network (I), a second address is assigned to each device (1 to 9) in addition to a first address which identifies the device in the first network (M). This second address is formed by connecting the first address to a mathematical formation algorithm, e.g. a prefix. This second address makes it possible to identify the devices linked with one another in the first network (M) as devices belonging to the second network. It is especially advantageous to choose the prefix in such a way that the second addresses are interpreted as private addresses in accordance with the definition rfe 1918. The inventive method is especially suited for communication between a private network, e.g. an MOST network (M) installed in a vehicle, and a public network, e.g. the Internet (I).

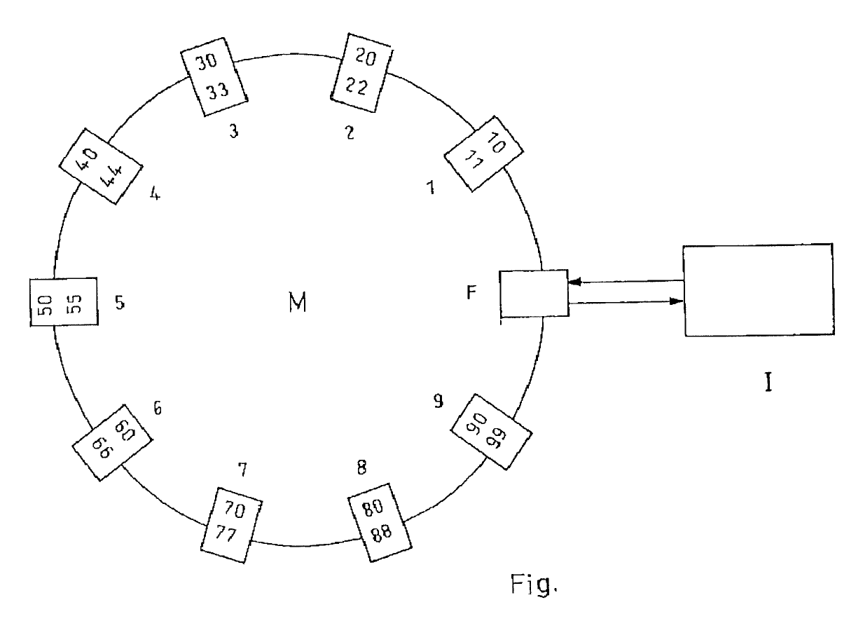

### DESCRIPTION

A Method for Generating a Second Address

The invention relates to a method for generating a second address to identify devices in a second network that can be linked to a first network, the devices in the first network being linked to one another and a first address being assigned to each device for identification in the first network.

So that devices linked in a first network can communicate with devices linked in a second network, the devices must be uniquely addressable.

The first network can be e.g. an MOST network, a multimedia system, with which motor vehicles of the most modern state-of-the-art are equipped, e.g. passenger cars, trucks, and buses. MOST is the abbreviation for media oriented systems transport or media oriented synchronous transfer. An MOST network has e.g. a ring structure and links several units, which serve as data sources, data sinks, or transceivers, as needed.

Just to list some examples of devices, an MOST network in a motor vehicle can link e.g. a radio receiver, a television receiver, a monitor, a CD player, a CD changer, a DVD player, a DVD changer, a cassette recorder, active loudspeakers, a navigation system, a car telephone, a wireless telephone, and operating and control units.

The second network can be e.g. the Internet.

It is now the object of the invention to specify a method for addressing devices linked in a first network so as to simplify communication with the devices linked in a second network and nevertheless provides high security against misconnections in the sense of data protection.

The invention achieves this object with the characteristics specified in claim 1 in that the second address of a device is generated by linking its first address with a mathematical formation algorithm.

Each of the devices linked to one another in the first network has an address assigned to it, by means of which the device can be identified in the first network. When the first network communicates with a second network, in which devices likewise are linked to one another, the inventive method assigns to each device of the first network a second address by means of which the devices of the first network can be identified as belonging to the second network. This second address is formed by linking the first address to a mathematical formation algorithm, so as to achieve a unique association between the addresses and the devices.

It is especially advantageous to choose a fixed prefix for this.

The invention will now be described and explained in exemplary fashion by means of an embodiment shown in the FIGURE.

The FIGURE shows an MOST network with nine devices 1 to 9. In addition to these devices 1 to 9, a so-called firewall F is present in the MOST network M.

A firewall is a computer which, as an interface, connects a private network—in this case the MOST network M—and a public network. In the FIGURE, the public network is the Internet I. Consequently, both the MOST network M and the Internet I have access to the firewall F. These two networks in a sense share the firewall.

A first address 10 to 90 is now assigned to each of the devices 1 to 9, such that each device in the MOST network can be identified by means of this address. By linking this first address to a prefix, a second address for each device 1 to 9 is generated. In the FIGURE, these second addresses are designated as 11, 22, 33, 44, 55, 66, 77, 88, and 99. By means of these second addresses, the devices 1 to 9, which are linked to one another in the first network—the MOST network—a are assigned to the second network—the Internet I. By means of these second addresses, the devices linked to one another in the first network can be uniquely identified by the second network.

It is especially advantageous to choose the prefix for generating the second address in such a way that the second addresses are interpreted as private addresses in accordance with the definition rfe 1918. This step considerably increases data protection and protection against mis-connections.

The inventive method is indeed especially well suited for communication between an MOST network and the Internet, but is in no way limited to this application. The inventive method is suited for networks of any type. Because high security against misconnections and excellent data protection are achieved with only little complexity, the inventive method is especially suited for communication between a private and a public network.

List of Reference Symbols

I Internet

M MOST network

F Firewall

10 to 90 First address

11 to 99 Second address

1. A method to generate a second address to identify devices (1 to 9) in a second network (I) which can be linked to a first network (M), the devices (1 to 9) in the first network (1 to 9) being linked with one another and a first address (10 to 90) being assigned to each device (1 to 9) for identification in the first network (M),
characterized in that the second address (11 to 99) of a device (1 to 9) is generated by connecting its first address (10 to 90) to a mathematical formation algorithm.

2. The method of claim 1,
characterized in that a fixed prefix is chosen for the mathematical formation algorithm.

3. The method of claim 2,
characterized in that the prefix is chosen so that the second address is interpreted as a private address in accordance with the definition rfe 1918.

4. The method of claim 1, 2, or 3,
characterized in that the first network is an MOST network (M).

5. The method of claim 1, 2, 3, or 4,
characterized in that the second network is the Internet (I).

6. The method of claim 5,
characterized in that a firewall (F) is present in the MOST network (M) as an interface between the MOST network (M) and the Internet (I).
